(19) United States
(12) Patent Application Publication
(10) Pub. No.: US 2010/0086877 A1
(43) Pub. Date: Apr. 8, 2010

(54) PATTERN FORMING METHOD AND PATTERN FORM

(75) Inventors: Munehisa Soma, Tokyo (JP); Gaku Suzuki, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 12/635,214

(22) Filed: Dec. 10, 2009

Related U.S. Application Data
(63) Continuation of application No. PCT/JP2008/062426, filed on Jul. 9, 2008.

(30) Foreign Application Priority Data
Dec. 17, 2007 (JP) 2007-324465
Jul. 9, 2008 (JP) 2008-554557

(51) Int. Cl. G03F 7/20

(52) U.S. Cl. 430/323

(57) ABSTRACT

One embodiment of the present invention is a pattern forming method for forming a fine three-dimensional structural pattern, including: forming a resist material film on a substrate having a projecting pattern on a step in such a manner as to cover at least a marginal portion of the projecting pattern such that the resist material film is heaped on the projecting pattern in conformity with the step; reducing the heaped resist material film formed by first etching until the marginal portion of the projecting pattern is exposed from an edge of the heaped resist material film; and forming an upper projecting pattern according to the projecting pattern in a self-aligning manner by second etching on the marginal portion of the exposed projecting pattern by using the reduced resist material film as a mask.

This application is a continuation of International Application No. PCT/JP2008/062426, filed Jul. 9, 2008, which claims the benefit of priority from the prior Japanese Patent Application No. 2007-324465, filed Dec. 17, 2007, the entire contents of both applications are incorporated herein by reference.

### TECHNICAL FIELD

The present invention relates to a pattern forming method and a pattern form.

### BACKGROUND ART

In recent years, there has been widely used a pattern form having a specified fine three-dimensional structural pattern (e.g., a multi-step form) formed on a substrate (made of, for example, glass, a resin, metal, silicon, or the like).

There are listed, for example, a semiconductor device, an optical device, a wiring circuit, a data storage medium (such as a hard disk or an optical medium), a medical member (such as a chip for analytical inspection or a micro needle), a biological device (such as a biosensor or a cell culture substrate), a member for precise inspection instrument (an inspection probe or a sample holding member), a display panel, a panel member, an energy device (such as a solar cell or a fuel cell), a micro channel, a micro reactor, an MEMS device, an imprint mold, a photo mask, and the like.

A three-dimensional structural pattern in such a pattern form has been demanded to have a more precise pattern or a more multi-step pattern.

In view of this, demand is developing for a pattern form having a three-dimensional structural pattern provided with a more precise pattern or a more multi-step structure.

For example, it has been known to use a pattern form having a three-dimensional structural pattern provided with a plurality of steps on a transparent substrate in a Levenson type photo mask used as a phase shift mask for resolving a pattern having a small linewidth.

Otherwise, it has been known to use a pattern form having a dual-damascene structure formed as a specified fine three-dimensional structural pattern in a wiring circuit.

Alternatively, it has been known to use a pattern form having a three-dimensional structural pattern formed thereon in an imprint mold for transferring a three-dimensional structural pattern.

In particular, the number of required processes can be reduced to about ⅓ by using an imprint mold of a three-step structure in the case where a dual-damascene structure is formed as a three-dimensional structural pattern. Therefore, expectations are growing that a pattern form having a three-dimensional structural pattern formed thereon is used as an imprint mold (see Reference Literature: Proc. of SPIE., vol. 5992, pp. 786-794 (2005)).

On the other hand, demand is developing for a pattern forming method for forming a pattern having a more precise pattern or a three-dimensional structural pattern provided with a more multi-step structure.

For example, a method for forming a resin in a stepwise manner by controlling an electron beam dose by electron beam lithography has been known as a pattern forming method for forming a three-dimensional structural pattern (see Reference Literature: Jpn. J. Appl. Phys., vol. 39, pp. 6831-6835 (2000)).

Otherwise, a method for eliminating a step by coating a first-step projecting pattern with BARC (Bottom Anti Reflection Coating), and then, forming a pattern again in forming a dual-damascene structure has been known as a pattern forming method for forming a three-dimensional structural pattern (see Reference Literature: Japanese Patent Application Laid-Open No. 2003-303824).

Alternatively, a method for forming a stepwise structure by lithography has been known as a pattern forming method for forming a three-dimensional structural pattern.

A description will be given below of a typical method for forming a three-dimensional structural pattern by lithography in the prior art with reference to FIGS. 1A to 1H.

First of all, a resist material film 13 is formed on a laminated substrate formed by laminating an upper material substrate 12 on a lower material substrate 11 (FIG. 1A). (Here, a resist material film 13 means a film of a resist material 13)

Next, the resist material film 13 is patterned, thereby forming a mask pattern 14 for a first-step projecting pattern (FIG. 1B).

Subsequently, the upper material substrate 12 is etched by using the mask pattern 14 as a mask, thereby forming a first-step upper material pattern 15. Furthermore, the lower material substrate 11 is etched by using the first-step upper material pattern 15 as a mask, thereby forming a first-step lower material pattern 16 (FIG. 1C).

Thereafter, the substrate is rinsed, thereby removing the mask pattern 14 for the first-step projecting pattern (FIG. 1D).

Next, another resist material film 13 is formed on the substrate having the first-step projecting pattern formed thereon (FIG. 1E).

Subsequently, the resist material film 13 is patterned, thereby forming a mask pattern 14 for a second-step projecting pattern (FIG. 1F).

Thereafter, the first-step upper material pattern 15 is etched by using the mask pattern 14 as a mask, thereby forming a second-step upper material pattern 17. Furthermore, the first-step lower material pattern 16 is etched by using the second-step upper material pattern 17 as a mask, thereby forming a second-step lower material pattern 18 (FIG. 1G).

Finally, the substrate is rinsed, thereby removing the mask pattern 14 for the second-step projecting pattern and the second-step upper material pattern 17 (FIG. 1H).

At this time, in forming the mask pattern made of the resist material after the formation of the first-step projecting pattern, it is very difficult to form the mask pattern made of the resist material at the center of the projecting pattern formed right under since alignment on a nano level is required between the projecting pattern formed right under and the mask pattern.

For example, as illustrated in FIGS. 2A and 2B, there arises a fear according to the precision of alignment that a mask pattern 19 deviated from the center of the projecting pattern formed right under may be formed on the first-step upper material pattern 15 and the first-step lower material pattern 16 serving as the projecting patterns formed right under.

As described above, it is difficult to form a mask pattern at a predetermined position with respect to a substrate already provided with a projecting pattern. This is because the alignment needs to be performed within the dimensional width of the projecting pattern already formed.

In particular, in the case where a fine pattern is required, the projecting pattern already formed has the dimensional width on a nano level. Therefore, the alignment on the nano level is required, thereby causing an extreme difficulty.

### SUMMARY OF THE INVENTION

The present invention has been accomplished to solve the above-described problem. Therefore, an object of the present invention is to provide a pattern forming method suitable for forming a fine three-dimensional structural pattern provided with a projecting pattern having a plurality of steps.

According to an embodiment of the present invention, a pattern forming method for forming a fine three-dimensional structural pattern includes: forming a projecting pattern on a substrate; forming a resist material film on the substrate having the projecting patterns formed in a stepwise manner; hardening the resist material so as to form a mask pattern; reducing the mask pattern; and etching the substrate by using the reduced mask pattern as a mask.

According to the present invention, the resist material may be a photosensitive material.

According to the present invention, the substrate may be a laminated substrate.

According to the present invention, the laminated substrate may be a laminated substrate obtained by laminating materials different in etching rate during etching.

According to the present invention, in hardening the resist material, the resist material may be hardened in a range wider than a dimensional width of an upper material of a desired three-dimensional structural pattern.

According to the present invention, in hardening the resist material, the resist material film may be formed over the entire substrate, and then, the resist material film formed over the entire substrate may be hardened.

According to the present invention, the resist material may remain in such a manner as to separately cover the projecting pattern formed on the substrate.

According to the present invention, the smallest dimensional width of the projecting pattern may be 500 nm or less.

According to the present invention, the pattern forming method may further include repeating once or more: forming the resist material film on the substrate; hardening the resist material so as to form the mask pattern; reducing the mask pattern; and etching the substrate by using the reduced mask pattern as the mask.

According to the present invention, the pattern forming method may further include transferring with a formed pattern form as an original print.

According to another embodiment of the present invention, a pattern form includes: a plurality of steps; and a marginal portion of an upper projecting pattern at a position substantially equidistant from a marginal portion of a projecting pattern formed right under.

In the pattern form according to the present invention, the smallest dimensional width of the projecting pattern formed right under may be 500 nm or less.

According to the present invention, the plurality of upper projecting patterns may correspond to one projecting pattern formed right under.

According to the present invention, the upper projecting pattern may be formed in a self-aligning manner at a center of the projecting pattern formed right under.

According to a further embodiment of the present invention, a pattern form is subjected to transferring by using the pattern form according to the present invention as an original print.

According to the present invention, the fine three-dimensional structural pattern provided with the projecting patterns on the plurality of steps can be suitably formed.

When the resist material film is formed on the substrate having the step, the resist material cannot be formed flat but it is heaped on the projecting pattern according to the step. As a consequence, the thin portion (i.e., the marginal portion of the heaped portion) is first reduced by hardening and reducing the formed resist material film, so that the mask pattern made of the resist material can be formed at the center of the projecting pattern formed right under in the self-aligning manner.

Thus, the mask can be formed at the center of the projecting pattern formed right under in the self-aligning manner on the substrate already provided with the projecting pattern, so that the fine three-dimensional structural pattern provided with the projecting patterns on the plurality of steps can be suitably formed.

### BRIEF DESCRIPTION OF THE DRAWINGS

FIGS. 1A to 1H are cross-sectional views showing processes in an embodiment of a pattern forming method in the prior art, wherein FIG. 1A shows a process for forming a resist material film on a first step; FIG. 1B shows a process for patterning the resist material film on the first step; FIG. 1C shows a process for etching a substrate on the first step; FIG. 1D shows a rinsing process on the first step; FIG. 1E shows a process for forming a resist material film on a second step; FIG. 1F shows a process for patterning the resist material film on the second step; FIG. 1G shows a process for etching a substrate on the second step; and FIG. 1H shows a rinsing process on the second step.

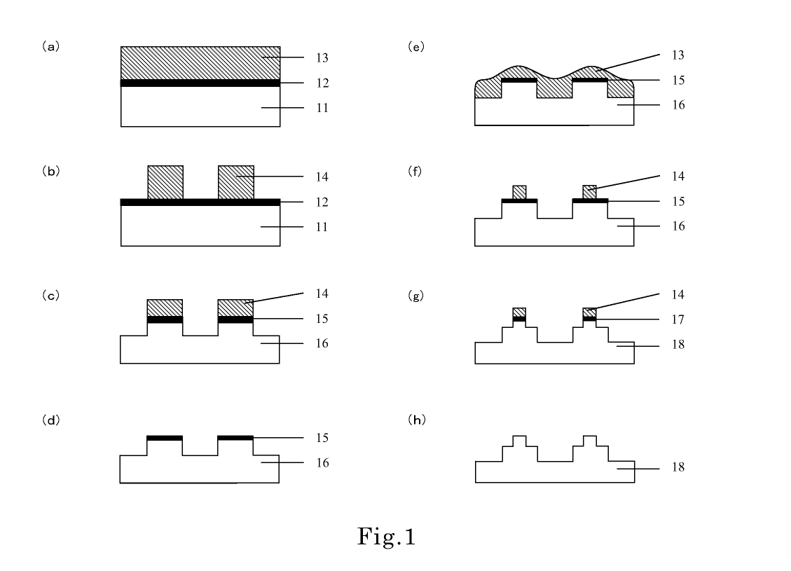

FIGS. 2A and 2B are explanatory views of a problem in the pattern forming method in the prior art, wherein FIG. 2A is a cross-sectional view cut along a line A-A' of a plan view; and FIG. 2B is the plan view.

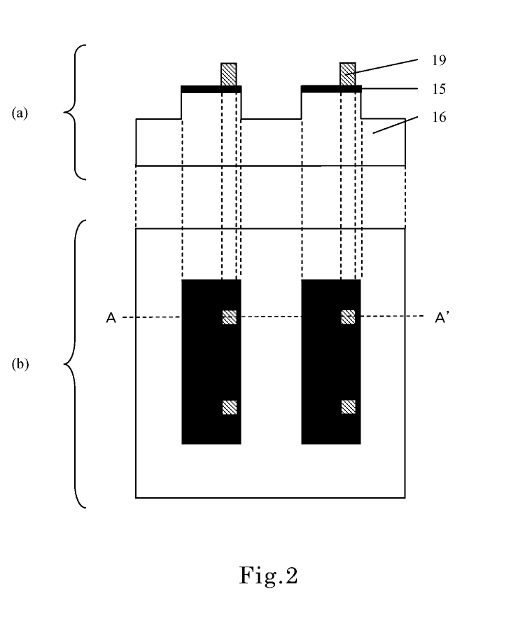

FIGS. 3A to 3K are cross-sectional views showing processes in an embodiment of a pattern forming method according to the present invention, wherein FIG. 3A shows a process for forming a resist material film on a first step; FIG. 3B shows a process for patterning the resist material film on the first step; FIG. 3C shows a process for etching a substrate on the first step; FIG. 3D shows a rinsing process on the first step; FIG. 3E shows a process for forming a resist material film on a second step; FIG. 3F shows a process for hardening the resist material film on the second step; FIG. 3G shows a process for reducing the hardened resist material film; FIG. 3H shows a process for etching an upper material substrate on the second step; FIG. 3I shows a rinsing process; FIG. 3J shows a process for etching a lower material substrate on the second step; and FIG. 3K shows a process for rinsing the upper material substrate.

FIGS. 4A and 4B are explanatory views of the process for hardening the resist material film in the pattern forming method according to the present invention, wherein FIG. 4A is a cross-sectional view cut along a line A-A' of a plan view; and FIG. 4B is the plan view.

FIGS. 5A to 5C are explanatory views of the process for reducing a mask pattern in the pattern forming method according to the present invention, wherein FIG. 5A is a cross-sectional view cut along a line A-A' of a plan view; FIG. 5B is the plan view; and FIG. 5C is an enlarged view showing the vicinity of a mask pattern.

FIGS. 6A to 6F are cross-sectional views showing processes in another embodiment of the pattern forming method according to the present invention, wherein FIG. 6A shows a process for preparing a substrate provided with a step; FIG. 6B shows a process for forming a resist material film on a second step; FIG. 6C shows a process for hardening the resist material film on the second step; FIG. 6D shows a process for reducing the hardened resist material film; FIG. 6E shows an etching process; and FIG. 6F shows a rinsing process.

### EXPLANATION OF REFERENCE NUMERALS

11 . . . lower material substrate
12 . . . upper material substrate
13 . . . electron beam resist (resist material)
14 . . . mask pattern
15 . . . upper material pattern on first step
16 . . . lower material pattern on first step
17 . . . upper material pattern on second step
18 . . . lower material pattern on second step
19 . . . mask pattern deviated from center of projecting pattern formed right under
20 . . . substrate
21 . . . pattern form

### BEST MODE FOR CARRYING OUT THE INVENTION

A description will be given below of a pattern forming method according to the present invention.

### <Process for Forming Step on Substrate>

First of all, a step is formed on a substrate.

At this time, the substrate is not particularly limited as long as it is provided with physical properties and mechanical properties suitable for a fine machining technique, described later.

For example, as the substrate may be used (1) a substrate containing SiO₂ such as quartz or glass; (2) a sapphire substrate; (3) a silicon substrate; (4) a substrate containing negatively expansive manganese nitride; (5) a silicon carbide substrate; (6) a glassy carbon substrate; and (7) a metallic substrate made of nickel, tantalum, or the like. Otherwise, the substrate may be a laminated substrate formed by laminating a plurality of materials (e.g., an SOI substrate).

In the case where the pattern forming method according to the present invention is used in an imprint mold for use in a UV imprinting method or a photo mask fabricating process, a substrate is required to transmit an exposure light beam to be used. Therefore, when the pattern forming method according to the present invention is used in the imprint mold for use in the UV imprinting method or the photo mask fabricating process, a quartz substrate having transparency with respect to a general exposure light beam can be suitably used.

It is preferable that the substrate be a laminated substrate formed by laminating materials having different etching rates in an etching process. The use of the substrate formed by laminating materials having different etching rates increases differences in etching rate between a resist material and an upper material and between the upper material and a lower material, thereby preferably achieving fine pattern formation.

For example, in the case where quartz is used as the lower material, a metallic thin film made of chromium, tantalum, or the like may be used as an upper material.

Moreover, as a method for forming a step on a substrate may be used a fine machining technique capable of forming a desired dimensional width of a pattern. For example, lithography, etching, fine machining (such as laser machining or machining), and the like may be used as the fine machining technique.

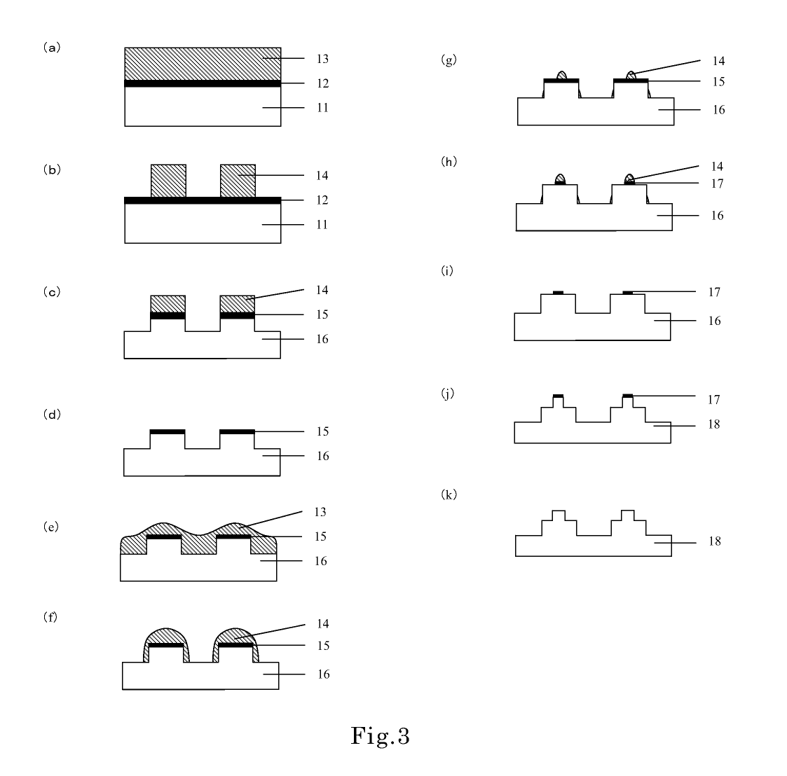

FIGS. 3A to 3D exemplify a method for forming a step on a substrate by lithography.

First of all, a resist material film 13 is formed on a laminated substrate formed by laminating an upper material substrate 12 on a lower material substrate 11 (FIG. 3A).

Next, the resist material film 13 is patterned, thereby forming a mask pattern 14 for a first-step projecting pattern (FIG. 3B).

Subsequently, the upper material substrate 12 is etched by using the mask pattern 14 as a mask, thereby forming a first-step upper material pattern 15. Furthermore, the lower material substrate 11 is etched by using the first-step upper material pattern 15 as a mask, thereby forming a first-step lower material pattern 16 (FIG. 3C).

Thereafter, the substrate is rinsed, thereby removing the mask pattern 14 for the first-step projecting pattern (FIG. 3D).

### <Process for Forming Resist Material Film>

Next, another resist material film is formed on the substrate provided with the projecting pattern with the step (FIG. 3E).

Any resist material may be used as long as (1) its etching rate is different from that of the substrate in etching, as described later; (2) it has fluidity; and (3) it is hardened due to outside conditions (such as heat, pressure, or light), and further, it may be either organic or inorganic.

For example, a thermosetting resin which is hardened by heat or a photosensitive material which is hardened by exposure light may be used as the resist material.

As the method for forming the resist material film may be appropriately used a known thin film forming technique according to the material. For example, dye coating, spin coating, or the like may be used.

When the resist material film is formed on the substrate having the step, the resist material film cannot be formed flat but is heaped on a projecting pattern of the step in conformity with the step.

The thickness of the resist material film may be appropriately determined according to a desired upper projecting pattern, a surface tension of the resist material film, and the step of the projecting pattern formed right under previously.

In addition, the film thickness may be calculated in accordance with a simulation using a calculator (the Monte Carlo method).

### <Process for Hardening Resist Material Film>

Next, the resist material film heaped on the projecting pattern of the step in conformity with the step is hardened as it is (FIG. 3F).

A hardening method according to a selected resist material may be used. For example, in the case of the use of the thermosetting resin, heat is applied to the resist material film. Otherwise, in the case of the use of the photosensitive material, the resist material film may be irradiated with an exposure light beam.

In the pattern forming method according to the present invention, it is preferable that the resist material film be hardened in a range greater than the desired dimensional width of the upper pattern. Even if the resist material film is hardened in the range greater than the desired dimensional width of the upper pattern, the dimensional width of the mask pattern made of the resist material can be adjusted in the subsequent “mask pattern reducing process.” Therefore, no strict alignment is required according to the scale of the dimensional width of the upper pattern, thus simplifying the pattern forming method.

As a consequence, according to the present invention, it is possible to preferably form a portion having a smallest dimensional width of a projecting pattern formed right under the upper projecting pattern in a desired three-dimensional structural pattern which is 500 nm or less, more preferably 300 nm or less, 100 nm or less, 45 nm or less, 32 nm or less, or 22 nm or less.

In contrast, the dimensional width of the upper projecting pattern is smaller than that of the projecting pattern formed right under. As a consequence, a three-dimensional structural pattern in 300 nm or less, more preferably, 200 nm or less, 100 nm or less, 45 nm or less, 32 nm or less, or 22 nm or less can be preferably formed according to the dimensional width of the projecting pattern formed right under.

When the resist material film is hardened in the range greater than the pattern dimensional width, the resist material film, for example, may be formed over the entire substrate, and then, the resist material film formed over the entire substrate may be hardened.

In particular, it is preferable that the resist material film be made of a photosensitive material which is hardened or separated with an exposure light beam, to be then patterned with the exposure light beam. At this time, examples of the exposure light beam include not only an infrared ray, an ultraviolet ray, and an ultimate ultraviolet ray but also a charged particle beam such as an electron beam or an ionic particle beam.

In patterning the resist material film with the exposure light beam, the residual range of the resist material film can be controlled, so that the mask pattern can be formed according to the desired three-dimensional structural pattern.

When a photosensitive material of a negative type is used as the resist material film, the hardening range of the resist material film can be controlled by hardening the resist material film with the exposure light beam, so that the residual range of the resist material film can be controlled.

In contrast, when a photosensitive material of a positive type is used as the resist material film, the resist material film is hardened, and then, the hardened resist material film is patterned with the exposure light beam, so that the residual range of the resist material film can be controlled.

In the case where the resist material film is patterned, the resist material film may be patterned in such a manner as to separately cover the projecting pattern formed right under. As a consequence, a fine three-dimensional structural pattern having a plurality of projections can be formed on the projecting pattern formed right under.

A fine three-dimensional structural pattern having a plurality of projections with respect to the projecting pattern formed right under is expected to be used as an imprint mold to be used in forming a dual-damascene structure.

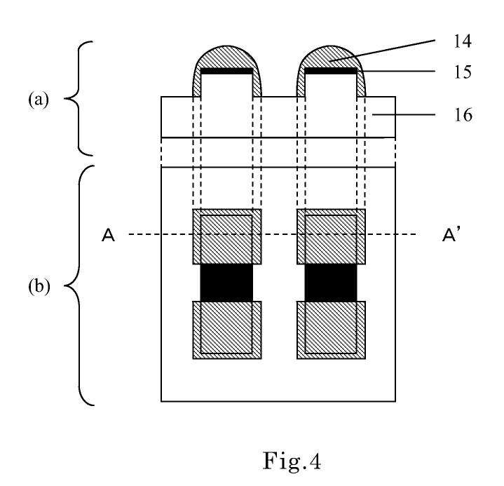

FIGS. 4A and 4B exemplify patterning a resist material film in such a manner as to separately cover a projecting pattern formed right under. A mask pattern 14 is formed in such a manner as to separately cover a first-step upper material pattern 15 and a first-step lower material pattern 16, which serve as projecting patterns formed right under, as shown in FIG. 4B.

When the resist material film is patterned with the exposure light beam, developing may be appropriately performed according to the resist material film which is used.

Rinsing may be performed together with the developing. Any rinsing may be performed with, for example, pure water, supercritical fluid, or the like as long as a developer liquid or foreign matters can be removed.

### <Process for Reducing Mask Pattern>

Next, the mask pattern made of the resist material is reduced (FIG. 3G).

The mask pattern is isotropically reduced, so that the resist material film remains at the center of the projecting pattern formed right under in a self-aligning manner.

In this manner, a pattern form having a marginal portion of the upper projecting pattern formed thereon can be formed at a position substantially equidistant from a marginal portion of the projecting pattern formed right under. Here, the substantially equidistant position is allowed to be ranged within 10% of the dimensional width of the projecting pattern formed right under.

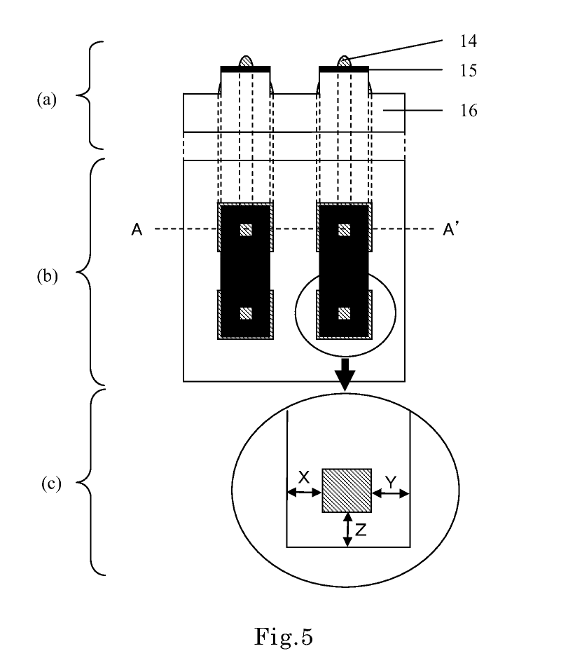

FIGS. 5A to 5C exemplify the mask pattern reduced isotropically. A marginal portion of the mask pattern 14 is formed at a portion substantially equidistant from a marginal portion of the projecting pattern formed right under with respect to the first-step upper material pattern 15 and the first-step lower material pattern 16 which are the projecting patterns formed right under, as illustrated in FIG. 5B. Therefore, a distance X, a distance Y, and a distance Z in FIG. 5C are substantially equal to each other.

The mask pattern may be appropriately reduced by a known method such as dry etching or wet etching according to the selected resist material.

In the case where the resist material film is reduced by etching, the etching is preferably performed under such a condition that the resist material film is reduced but the substrate is not etched. In addition, the etching condition may be properly adjusted according to the desired dimensional width of the pattern.

### <Process for Etching>

Subsequently, the substrate is etched by using the residual resist material film as a mask.

The substrate may be appropriately etched by a known method, for example, dry etching, wet etching, or the like. The etching condition may be properly adjusted according to an etching rate obtained by dividing the resist material film by the substrate to be used.

FIG. 3 illustrates the case of the use of the laminated substrate obtained by laminating the upper material substrate 12 on the lower material substrate 11. FIG. 3H illustrates a process for forming a second-step upper material pattern 17 by etching with the residual mask pattern 14 as a mask; FIG. 3I illustrates a process for rinsing the mask pattern 14; FIG. 3J illustrates a process for forming a second-step lower material pattern 18 by etching with the second-step upper material pattern as a mask; and FIG. 3K illustrates a process for peeling and rinsing the residual second-step upper material pattern 17.

Through the above-described processes, the pattern forming method according to the present invention can be carried out, and further, the pattern form having the projecting patterns with the plurality of steps can be obtained.

According to the present invention, the resist material film is further formed on the pattern form having the projecting patterns with the plurality of steps, to be then hardened, thereby forming the mask pattern. The mask pattern is reduced, and then, the substrate may be etched once or more by repetition by using the reduced mask pattern as a mask. As a consequence, the pattern forming method according to the present invention can provide the multi-step three-dimensional structural pattern form (a pattern form provided with projecting patterns with, for example, three steps or more).

Otherwise, according to the present invention, transferring may be further performed by using the obtained pattern form as an original mold. The transferring can provide a pattern form having a shape inverse to that of the obtained pattern form. The pattern form having the inverse shape is expected to be used in a wide field.

Alternatively, the pattern form having the inverse shape is used as a replica mold, thereby fabricating many pattern forms with the same replica mold, so as to reduce a production cost and enhance productivity. At this time, a transferring material can be selected without giving any consideration to machining characteristics with respect to the fine machining, and therefore, the material suitable for use of the pattern form can be selected.

### Example 1

The pattern forming method according to the present invention will be specifically described below by way of formation of a UV imprint mold with reference to FIGS. 3A to 3K. It should be naturally understood that the pattern forming method according to the present invention is not limited to the following examples.

A laminated substrate was prepared as a substrate by laminating an upper material substrate 12 on a lower material substrate 11.

Here, in this example, the lower material substrate 11 was made of quartz whereas the upper material substrate 12 was made of chromium.

Next, the laminated substrate was coated with a positive type as an electron beam resist 13 in a thickness of 200 nm (FIG. 3A). (Here, a positive type as an electron beam resist 13 means a photosensitive material of a positive type as a resist material 13.)

Subsequently, the electron beam resist 13 was hardened by heat, and then, was irradiated with (written by) an electron beam in a dose of 100 μC/cm² by a Variable Shaped Beam tool, followed by patterning. (Here, the electron beam resist 13 means the resist material 13.)

Thereafter, the electron beam resist 13 was developed with a developer liquid, to be then rinsed, and further, a rinsing liquid was dried (FIG. 3B). At this time, pure water was used as the rinsing liquid.

Next, the lower material substrate 11 and the upper material substrate 12 were etched by using, as a mask, a mask pattern 14 made of the patterned electron beam resist 13 by dry etching by using an ICP dry etching device (FIG. 3C).

At this time, chromium in the upper material substrate 12 was etched under conditions of a Cl₂ flow rate of 40 sccm, an O₂ flow rate of 10 sccm, an He flow rate of 80 sccm, a pressure of 30 Pa, an ICP power of 300 W, and an RIE power of 30 W.

In contrast, quartz in the lower material substrate 11 was etched under conditions of a C₄F₈ flow rate of 10 sccm, an O₂ flow rate of 10 to 25 sccm, an Ar flow rate of 75 sccm, a pressure of 2 Pa, an ICP power of 200 W, and an RIE power of 550 W.

In addition, the lower material substrate 11 was dry-etched in a depth of 250 nm.

Subsequently, the electron beam resist 13 was peeled off by O₂ plasma asking (under conditions of an O₂ flow rate of 500 sccm, a pressure of 30 Pa, and an RF power of 1000 W) (FIG. 3D).

In this manner, a first-step projecting pattern (having a dimensional width of 200 nm and a depth of 250 nm) could be formed.

Thereafter, a positive type as another electron beam resist 13 was formed in a thickness of 300 nm on the laminated substrate provided with the first-step projecting pattern having a step (FIG. 3E).

Subsequently, the electron beam resist 13 was hardened by heat, and then, was irradiated with (written by) an electron beam in a dose of 100 μC/cm² by a Variable Shaped Beam tool, followed by patterning.

At this time, the electron beam resist 13 remained at an area wider than a desired upper pattern in such a manner as to separately cover the first-step projecting pattern formed right under (FIGS. 4A and 4B).

Thereafter, the electron beam resist 13 was developed with a developer liquid, to be then rinsed, and further, a rinsing liquid was dried. Moreover, a mask pattern 14 was formed on the step (FIG. 3F). At this time, pure water was used as the rinsing liquid.

Subsequently, the mask pattern 14 made of the electron beam resist 13 was reduced by O₂ plasma ashing (FIGS. 3G and 5A to 5C).

At this time, the ashing conditions were an O₂ flow rate of 500 sccm, a pressure of 30 Pa, and an RF power of 300 W.

Next, the upper material substrate 12 was etched by using, as a mask, the mask pattern 14 made of the electron beam resist 13 by dry etching by using an ICP dry etching device (FIG. 3H).

At this time, chromium in the upper material substrate 12 was etched under conditions of a Cl₂ flow rate of 40 sccm, an O₂ flow rate of 10 sccm, an He flow rate of 80 sccm, a pressure of 30 Pa, an ICP power of 300 W, and an RIE power of 30 W.

Subsequently, the residual mask pattern 14 was peeled off and rinsed by the O₂ plasma asking (FIG. 3I).

Next, the first-step lower material pattern 16 was etched by using, as a mask, a second-step upper material pattern 17 by the dry etching by using the ICP dry etching device (FIG. 3J).

At this time, quartz in the lower material substrate 11 was etched under conditions of a C₄F₈ flow rate of 10 sccm, an O₂ flow rate of 10 to 25 sccm, an Ar flow rate of 75 sccm, a pressure of 2 Pa, an ICP power of 200 W, and an RIE power of 550 W.

In addition, the lower material substrate 11 was etched by dry etching in a depth of 200 nm.

Thereafter, the residual second-step upper material pattern 17 was peeled off by wet etching, to be rinsed (FIG. 3K).

Through the above-described processes, the UV imprint mold provided with the projecting patterns with the plurality of steps could be fabricated by using the pattern forming method according to the present invention.

The resultant UV imprint mold was photographed by SEM, and then, the SEM photograph was observed. Upon measurement of distances from a marginal portion of the projecting pattern formed right under to a marginal portion of the upper projecting pattern based on the SEM photograph, the distances were substantially equal to each other.

### Example 2

The pattern forming method according to the present invention will be described below by way of another example.

A silicon substrate was prepared as a substrate 20.

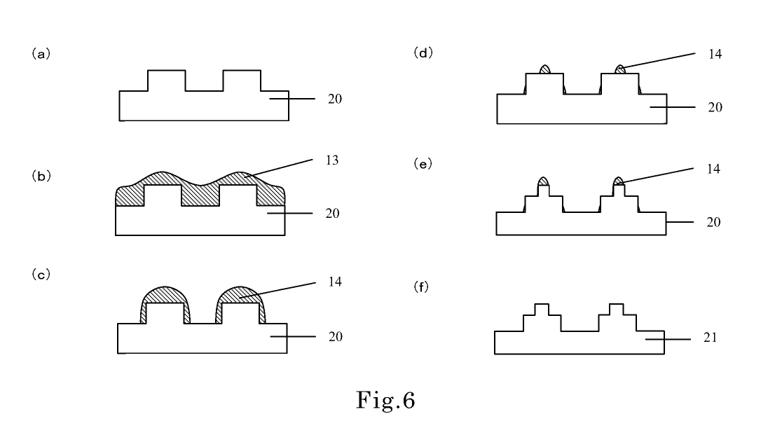

Next, a first-step projecting pattern (having a dimensional width of 150 nm and a depth of 200 nm) was formed by using a fine machine (FIG. 6A).

Subsequently, a negative type was formed as an electron beam resist 13 in a thickness of 300 nm on the substrate 20 having the first-step projecting pattern (FIG. 6B).

Thereafter, the electron beam resist 13 was irradiated with (written by) an electron beam in a dose of 100 μC/cm² by a Variable Shaped Beam tool. At this time, the electron beam resist 13 was irradiated (written) at an area wider than a desired upper pattern in such a manner as to separately cover the first-step projecting pattern formed right under (FIG. 4).

Thereafter, the electron beam resist 13 was developed with a developer liquid, to be then rinsed, and further, a rinsing liquid was dried. Moreover, a mask pattern 14 was formed on the first-step projecting pattern (FIG. 6C). At this time, pure water was used as the rinsing liquid.

Subsequently, the mask pattern 14 made of the electron beam resist 13 was reduced by O₂ plasma ashing (FIGS. 6D and 5A to 5C).

At this time, the ashing conditions were an O₂ flow rate of 500 sccm, a pressure of 30 Pa, and an RF power of 300 W.

Next, the substrate 20 was etched by using, as a mask, the mask pattern 14 made of the electron beam resist 13 by dry etching by using an ICP dry etching device (FIG. 6E).

At this time, silicon in the substrate 20 was etched under conditions of a C₄F₂ flow rate of 30 sccm, an O₂ flow rate of 30 sccm, an Ar flow rate of 50 sccm, a pressure of 2 Pa, an ICP power of 500 W, and an RIE power of 130 W.

Subsequently, the residual electron beam resist 13 was peeled off and rinsed (FIG. 6F).

The above-described processes could provide a pattern form 21 made of silicon provided with the projecting patterns having a plurality of steps.

The resultant pattern form 21 was photographed by the SEM, and then, the SEM photograph was observed.

Upon measurement of distances from a marginal portion of the projecting pattern formed right under to a marginal portion of the upper projecting pattern based on the SEM photograph, the distances were substantially equal to each other.

### INDUSTRIAL APPLICABILITY

The pattern forming method and the pattern form formed by the pattern forming method according to the present invention are expected to be utilized in a wide field, in which a fine three-dimensional structural pattern is required to be formed.

There are listed, for example, a semiconductor device, an optical device, a wiring circuit, a data storage medium (such as a hard disk or an optical medium), a medical member (such as a chip for analytical inspection or a micro needle), a biological device (such as a biosensor or a cell culture substrate), a member for precise inspection instrument (an inspection probe or a sample holding member), a display panel, a panel member, an energy device (such as a solar cell or a fuel cell), a micro channel, a micro reactor, an MEMS device, an imprint mold, a photo mask, and the like.

What is claimed is:

1. A pattern forming method for forming a fine three-dimensional structural pattern, comprising:
forming a resist material film on a substrate having a projecting pattern with a step in such a manner as to cover at least a marginal portion of the projecting pattern such that the resist material film is heaped on the projecting pattern in conformity with the step;
reducing the heaped resist material film by etching until the marginal portion of the projecting pattern is exposed from an edge of the heaped resist material film; and
forming an upper projecting pattern on the projecting pattern in a self-aligning manner by etching the marginal portion of the exposed projecting pattern by using the reduced resist material film as a mask.

2. The pattern forming method according to claim 1, wherein the resist material is a photosensitive material.

3. The pattern forming method according to claim 1, wherein the substrate is a laminated substrate.

4. The pattern forming method according to claim 3, wherein the laminated substrate is a laminated substrate obtained by laminating materials different in etching rate during etching.

5. The pattern forming method according to claim 1, wherein in forming the resist material film, the resist material film is formed in a range wider than a dimensional width of an upper material of a desired three-dimensional structural pattern.

6. The pattern forming method according to claim 5, wherein in forming the resist material film, the resist material film is formed over the entire substrate.

7. The pattern forming method according to claim 1, wherein the resist material film remains in such a manner as to separately cover the marginal portions of the projecting patterns formed on the substrate.

8. The pattern forming method according to claim 1, wherein the smallest dimensional width of the projecting pattern is 500 nm or less.

9. The pattern forming method according to claim 1, further comprising repeating once or more:
forming the resist material film on the substrate;
reducing the resist material film which was hardened; and
etching the projecting pattern by using the reduced resist material film as a mask.

10. A pattern forming method, comprising:
transferring with a pattern form formed by the pattern forming method according to claim 1 as an original mold.
